(19) United States
(12) Patent Application Publication
(10) Pub. No.: US 2014/0008661 A1
(43) Pub. Date: Jan. 9, 2014

(54) NITRIDE-BASED COMPOUND SEMICONDUCTOR DEVICE

(71) Applicant: Advanced Power Device Research Association, Yokohama-shi (JP)

(72) Inventors: Masayuki IWAMI, Kanagawa (JP); Takuya KOKAWA, Kanagawa (JP)

(21) Appl. No.: 13/935,834

(22) Filed: Jul. 5, 2013

(30) Foreign Application Priority Data
Jul. 5, 2012 (JP) 2012-151740

(51) Int. Cl. H01L 29/20; H01L 29/205

(52) U.S. Cl. CPC H01L 29/2003; H01L 29/205
USPC 257/76

(57) ABSTRACT

A nitride-based compound semiconductor device includes a substrate, a first nitride-based compound semiconductor layer that is formed above the substrate with a buffer layer interposed between them, a second nitride-based compound semiconductor layer that is formed on the first nitride-based compound semiconductor layer and that has a larger band gap than a band gap of the first nitride-based compound semiconductor layer, and an electrode that is formed on the second nitride-based compound semiconductor layer. The second nitride-based compound semiconductor layer has a region in which carbon is doped near a surface of the second nitride-based compound semiconductor layer.

### CROSS-REFERENCE TO RELATED APPLICATION(S)

The present application claims priority to and incorporates by reference the entire contents of Japanese Patent Application No. 2012-151740 filed in Japan on Jul. 5, 2012.

### BACKGROUND OF THE INVENTION

1. Field of the Invention

The present invention relates to a nitride-based compound semiconductor device.

2. Description of the Related Art

Because a nitride-based compound semiconductor such as a gallium nitride (GaN)-based semiconductor has a larger band gap energy and a higher breakdown voltage than those of a silicon-based material, a semiconductor device having a low ON-resistance and operating in a high temperature environment can be manufactured using a nitride-based compound semiconductor. Therefore, a GaN-based semiconductor is highly expected as a material substituting a silicon-based material for a power device such as an inverter or a converter. In particular, an aluminum gallium nitride (AlGaN)/GaN-heterojunction field-effect transistor (HFET) that is a field-effect transistor using an AlGaN/GaN heterostructure is highly expected as a high-frequency device.

A high OFF-state breakdown voltage is an important parameter for a power device because the breakdown voltage determines the maximum output of a transistor, for example. In order to achieve a high OFF-state breakdown voltage, it is required to achieve a high buffer breakdown voltage. In other words, it is required to reduce a leakage current.

A Schottky leakage on a nitride-based compound semiconductor surface can be explained using what is called a surface donor model (see J. Kotani, H. Hasegawa, and T. Hashizume, Applied Surface Science 2004, vol. 237, p. 213). According to the surface donor model, the surface of an epitaxially grown nitride-based compound semiconductor has nitrogen vacancies (V_{N}) generated by desorption of nitrogen atoms, and the nitrogen vacancies form shallow donor levels in a region between 10 nanometers and 30 nanometers from the surface. Such donor levels result in a high donor density on the surface of the nitride-based compound semiconductor and make it difficult to reduce the Schottky leakage.

As an example of a countermeasure for reducing the Schottky leakage, disclosed is a method in which, in an AlGaN/GaN-HFET structure, residual carriers in the AlGaN layer that is a barrier (electron-supplying) layer are compensated by doping carbon in the AlGaN layer (see Japanese Patent Application Laid-open No. 2010-171416). Examples of a method for doping carbon during an epitaxial growth of a nitride-based compound semiconductor layer include autodoping (see Japanese Patent Application Laid-open No. 2007-251144) and a doping method using hydrocarbon (see Japanese Patent Application Laid-open No. 2010-239034).

### SUMMARY OF THE INVENTION

It is an object of the present invention to at least partially solve the problems in the conventional technology.

In accordance with one aspect of the present invention, a nitride-based compound semiconductor device includes a substrate, a first nitride-based compound semiconductor layer that is formed above the substrate with a buffer layer interposed between them, a second nitride-based compound semiconductor layer that is formed on the first nitride-based compound semiconductor layer and that has a larger band gap than a band gap of the first nitride-based compound semiconductor layer, and an electrode that is formed on the second nitride-based compound semiconductor layer. The second nitride-based compound semiconductor layer has a region in which carbon is doped near a surface of the second nitride-based compound semiconductor layer.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic of an atomic model;

FIG. 2 is a graph of a density of states (DOS) of electron in a model having no defect on the surface;

FIG. 3 is a graph of a DOS of electron of a model in which a nitrogen atom is substituted with a vacancy;

FIG. 4 is a graph of a DOS of electron in a model in which the vacancy is substituted with a carbon atom;

FIG. 5 is a graph of the number of surface levels and cohesive energy per number of atoms in each of these models;

FIG. 6 is a schematic cross-sectional view of an HFET that is a nitride-based compound semiconductor device according to a first embodiment of the present invention;

FIGS. 7 and 8 are a schematic for explaining a process of manufacturing the HFET illustrated in FIG. 6;

FIG. 9 is a schematic for explaining a reaction on the surface of the epitaxial layer;

FIG. 10 is a graph of gate leakage characteristics of the example and of the comparative example;

FIG. 11 is a graph of ON characteristics of the example and of the comparative example;

FIG. 12 is a schematic cross-sectional view of a metal-oxide-semiconductor field-effect transistor (MOSFET) that is a nitride-based compound semiconductor device according to a second embodiment of the present invention;

FIGS. 13 and 14 are a schematic for explaining a process of manufacturing the MOSFET illustrated in FIG. 12;

FIG. 15 is a schematic cross-sectional view of a Schottky barrier diode (SBD) that is a nitride-based compound semiconductor device according to a third embodiment of the present invention;

FIG. 16 is a top view of the SBD illustrated in FIG. 15;

FIGS. 17 and 18 are a schematic for explaining a process of manufacturing the SBD illustrated in FIG. 15; and

FIG. 19 is a graph of a profile of implanted carbon atoms.

### DETAILED DESCRIPTION OF THE PREFERRED EMBODIMENTS

According to the disclosure in Japanese Patent Application Laid-open No. 2010-171416, because carbon is uniformly doped in the AlGaN layer, carbon could reduce the density of two-dimensional electron gas (2DEG) that is present in an electron transit layer (GaN layer) or reduce the mobility because of impurity scattering, and the ON-resistance could be increased, for example, disadvantageously. Furthermore, because the density of deep levels formed by carbon is increased, a current collapse phenomenon is worsened, disadvantageously.

In contrast, according to embodiments of the present invention explained below, because the second nitride-based compound semiconductor layer has a carbon-doped region near the surface of the second nitride-based compound semiconductor layer on the surface of which electrodes are formed, a nitride-based compound semiconductor device in which with the low leakage current and the current collapse phenomenon are reduced can be achieved without adversely affecting 2DEG.

Characteristic Evaluation through First-Principles Electronic Structure Calculation

To begin with, explained now is a result of a first-principles electronic structure calculation (simulation) conducted to evaluate how nitrogen vacancies (V_{N}) affects the electrical properties, and how effective carbon doping is, on the surface of a GaN crystal.

For the simulation, Advance/PHASE manufactured by AdvanceSoft Corporation was used. A Vanderbilt-type ultrasoft pseudopotential was used in the calculation. The exchange interaction was calculated within a range of generalized gradient approximation.

The conditions below were mainly used in the calculation:
atomic model: a slab model consisting of eighty four atoms (forty gallium atoms, forty nitrogen atoms (one of which is to be substituted with a vacancy or a carbon atom), and four hydrogen atoms), and a ten-angstrom vacuum layer.
cut-off energy: 25Ry and 230Ry, respectively, for the wave function and the charge density distribution
k-point samples: 3×3×1
number of bands calculated: 364

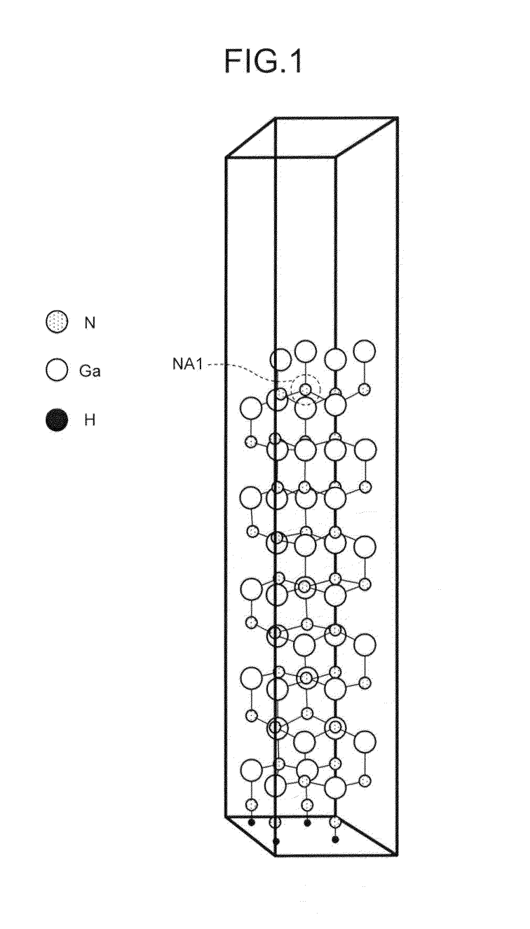

FIG. 1 illustrates the atomic model used in the simulation. Above the atoms is the ten-angstrom vacuum layer. In FIG. 1, the calculation was conducted by substituting the nitrogen atom NA1 near the surface with a vacancy or with a carbon atom.

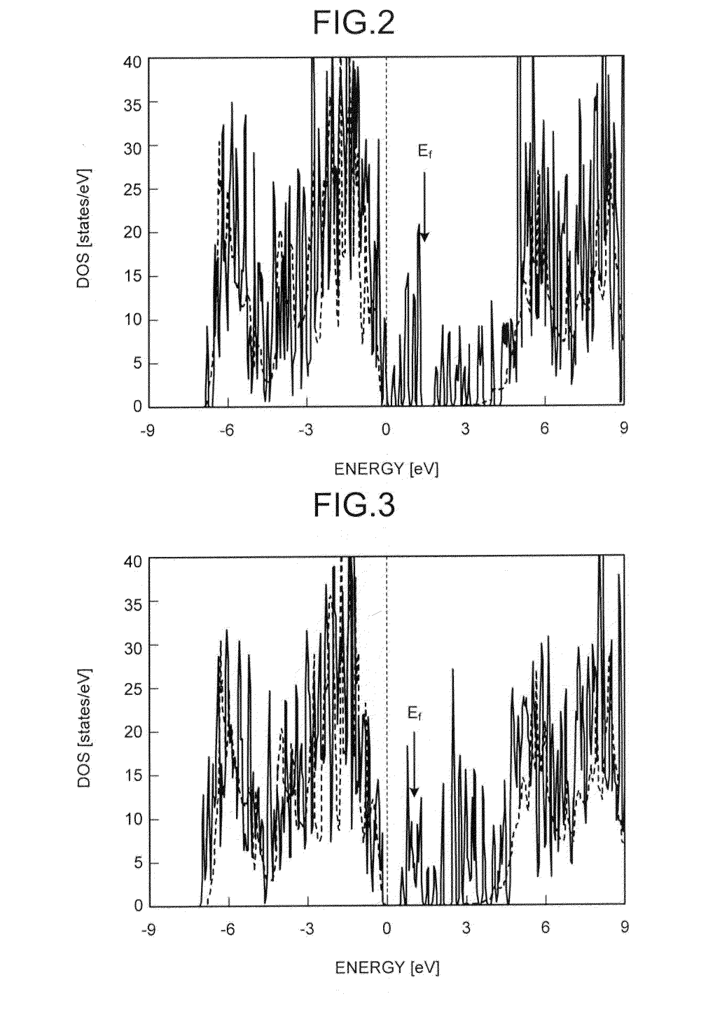

FIGS. 2, 3, and 4 are graphs of a density of states (DOS) of electron in a model having no defect on the surface, of a DOS of electron in a model in which the nitrogen atom is substituted with a vacancy, and of a DOS of electron in a model in which the vacancy is substituted with a carbon atom, respectively. In FIGS. 2 to 4, the DOS in a bulk GaN crystal is plotted in a dotted line in an overlapping manner for comparison. The point of origin of the energy is at valence band maximum (VBM). E_{f} represents Fermi energy.

As illustrated in FIG. 2, on a GaN surface without any defect, it can be seen that the surface levels are formed near E_{f} and from the midgap toward the conduction band minimum (CBM).

As illustrated in FIG. 3, when V_{N} is introduced to the surface, it can be seen that the number of donor levels below the CBM increased. These donor levels become a cause of a Schottky leakage. The levels near E_{f} become a cause of a current collapse phenomenon.

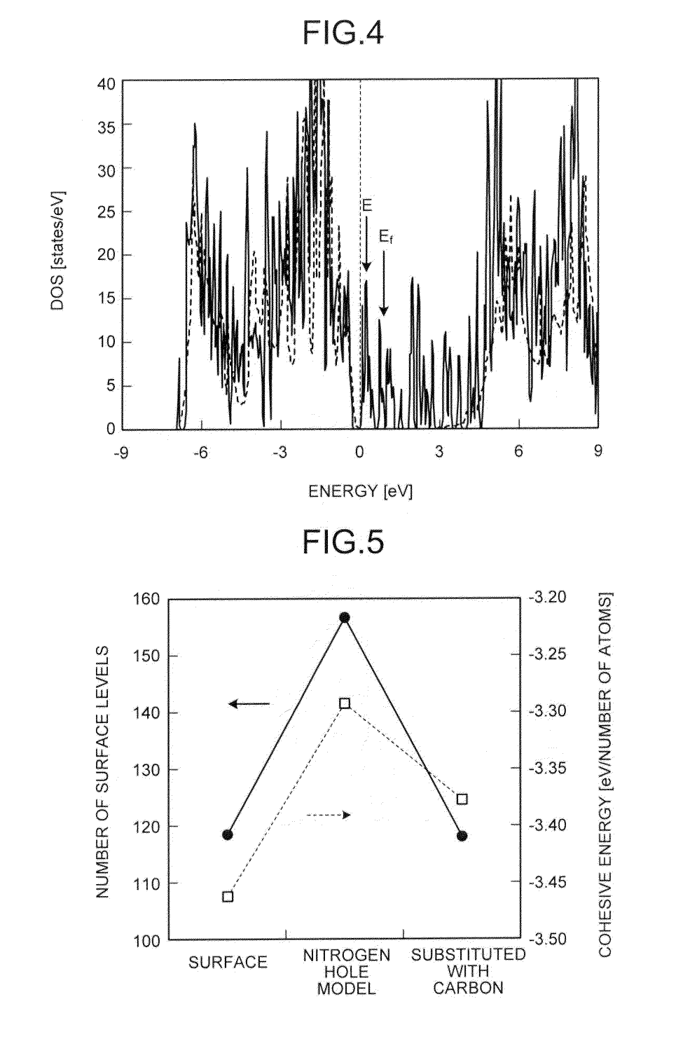

When the V_{N} is substituted with a carbon atom, as illustrated in FIG. 4, the levels under the CBM and those near E_{f} are both reduced (hereinafter, the carbon atom substituting V_{N} is referred to as C_{N}). Furthermore, because a shallow acceptor level E can be produced at the VBM, residual carriers can be compensated. In this manner, introduction of C_{N} can be expected to reduce a Schottky leakage, and to suppress a current collapse phenomenon, advantageously.

FIG. 5 is a graph of the number of surface levels and cohesive energy per number of atoms in each of these models. As illustrated in FIG. 5, the number of surface levels having increased by introduction of V_{N} is reduced by approximately 30 percent when V_{N} is substituted with C_{N}, and this number is approximately equal to that in the GaN surface without any defect. Because the cohesive energy in the system is reduced by substituting V_{N} with C_{N}, the carbon atom introduced to the surface can form C_{N} easily.

Explained above is the result of simulating a GaN surface, but a similar results is acquired for an AlGaN surface.

### Embodiments

Nitride-based compound semiconductor devices according to embodiments of the present invention will now be explained in detail with reference to the accompanying drawings. The embodiments are not intended to limit the scope of the present invention in any way. In the drawings, the same or corresponding elements are assigned with the same reference numerals. It should be noted that the drawings are schematic representations, and the thickness of each layer, a thickness ratio, and the like are different from those in reality. Furthermore, some parts are depicted in a different size relationship or in a different size ratio among some of these drawings.

### First Embodiment

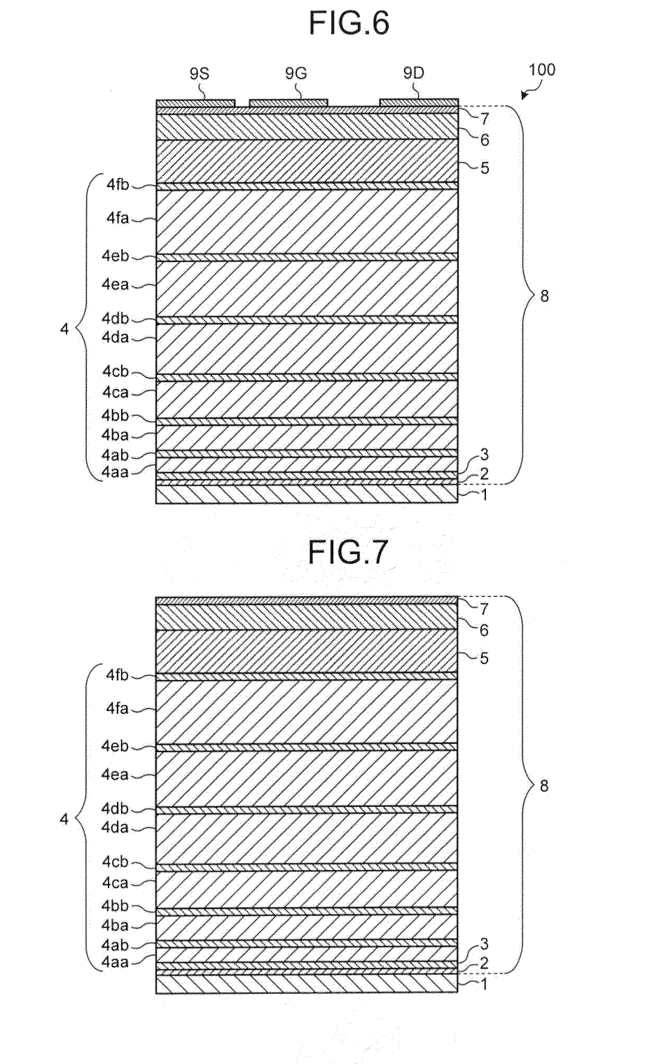

FIG. 6 is a schematic cross-sectional view of a heterojunction field-effect transistor (HFET) that is a nitride-based compound semiconductor device according to a first embodiment of the present invention.

An HFET 100 includes a silicon substrate 1 whose principal plane is a (111) plane and an epitaxial layer 8. The epitaxial layer 8 includes a silicon nitride layer 2, a seed layer 3 made of aluminum nitride (AlN), a buffer layer 4 in which GaN layers 4aa, 4ba, 4ca, 4da, 4ea, and 4fa and AlN layers 4ab, 4bb, 4cb, 4db, 4eb, 4fb are alternately stacked for six periods, a high-resistance layer 5 made of GaN, a GaN layer 6 serving as a first nitride-based compound semiconductor layer that functions as an electron transit (channel) layer, and an AlGaN layer 7 serving as a second nitride-based compound semiconductor layer that functions as an electron-supplying layer, which are formed sequentially on the silicon substrate 1. The HFET 100 also includes a source electrode 9S, a gate electrode 9G, and a drain electrode 9D all of which are formed on the surface of the AlGaN layer 7. In other words, the HFET 100 is an AlGaN/GaN-HFET having AlGaN/GaN heterojunctions. In the GaN layer 6, two-dimensional electron gas is formed near the interface with the AlGaN layer 7.

In the HFET 100, because the AlGaN layer 7 has a carbon-doped region near the surface, the nitrogen vacancies near the surface are substituted with carbon atoms. Therefore, the Schottky leakage current is low, and the current collapse phenomenon is reduced.

An example of a method for manufacturing the HFET 100 will now be explained. FIG. 7 is a schematic for explaining a process of fabricating an epitaxial substrate in the process of manufacturing the HFET 100 illustrated in FIG. 6.

1. Fabricating Epitaxial Substrate:

To begin with, to fabricate an epitaxial substrate, the epitaxial layer 8 is formed on the silicon substrate 1.

Specifically, the silicon nitride layer 2 is formed by introducing ammonia (NH₃) at a temperature of 1000 degrees Celsius at a flow rate of 35 L/min for 0.3 minute into metal-organic chemical vapor deposition (MOCVD) equipment in which the silicon substrate 1 (plane orientation (111)) grown in a Czochralski (CZ) process and having a diameter of four inches (approximately 100 millimeters) and a thickness of one millimeter is installed.

Trimethylaluminium (TMAl) and NH₃ are then introduced at a flow rate of 175 μmol/min and a flow rate of 35 L/min, respectively, and the seed layer 3 made of AlN and having a layer thickness of 40 nanometers is epitaxially grown on the silicon nitride layer 2 at a growth temperature of 1000 degrees Celsius.

The buffer layer 4 is then formed on the seed layer 3. The layer thicknesses of the GaN layers 4aa, 4ba, 4ca, 4da, 4ea, and 4fa are 290 nanometers, 340 nanometers, 390 nanometers, 450 nanometers, 560 nanometers, and 720 nanometers, respectively. The layer thicknesses of the AlN layers 4ab, 4bb, 4cb, 4db, 4eb, and 4fb are all 50 nanometers.

By stacking the buffer layer 4, cracking of the epitaxial layer 8 is suppressed, and the amount of warpage can also be controlled. Furthermore, by gradually increasing the layer thicknesses of the GaN layers from the side of the silicon substrate 1, the effects of suppressing cracks and controlling the amount of warpage can be increased to thicken the epitaxial layer 8 to be stacked.

The flow rates of TMAl, trimethylgallium (TMGa), and NH₃ of when the AlN layers and the GaN layer are grown are 195 μmol/min, 58 μmol/min, and 12 L/min, respectively.

The high-resistance layer 5 made of GaN is stacked at a layer thickness of 600 nanometers on the buffer layer 4 under conditions of a growth temperature of 1050 degrees Celsius and a growth pressure of 50 Torr. The flow rate of TMGa and the flow rate of NH₃ of when the high-resistance layer 5 is formed are 58 μmol/min and 12 L/min, respectively. A carbon density in the high-resistance layer 5 equal to or larger than 1×10¹⁸ cm⁻³ is preferable because such a density has an effect of reducing a buffer leakage.

TMGa and NH₃ are then introduced at a flow rate of 19 μmol/min and a flow rate of 12 L/min, respectively, and the GaN layer 6 is then epitaxially grown on the high-resistance layer 5 at a layer thickness of 100 nanometers. The growth temperature of the GaN layer 6 is 1050 degrees Celsius, and the growth pressure is 200 Torr. A carbon density in the GaN layer 6 equal to or smaller than 1×10¹⁸ cm⁻³ is preferable because such a density will not have any adverse effect on the two-dimensional electron gas density or the electron mobility.

TMAl, TMGa, and NH₃ are then introduced at a flow rate of 100 μmol/min, a flow rate of 19 μmol/min, and a flow rate of 12 L/min, respectively, and the AlGaN layer 7 at a layer thickness 25 nanometers is epitaxially grown on the GaN layer 6 at a growth temperature of 1060 degrees Celsius. The aluminum composition in the AlGaN layer 7 is 0.22. The aluminum composition can be evaluated from an X-ray diffraction, for example.

The epitaxial substrate is fabricated through the fabricating process explained above.

2. Doping Carbon Using Tandem Accelerator:

The epitaxial substrate fabricated at the above-described process 1 is then irradiated with nitrogen ion.

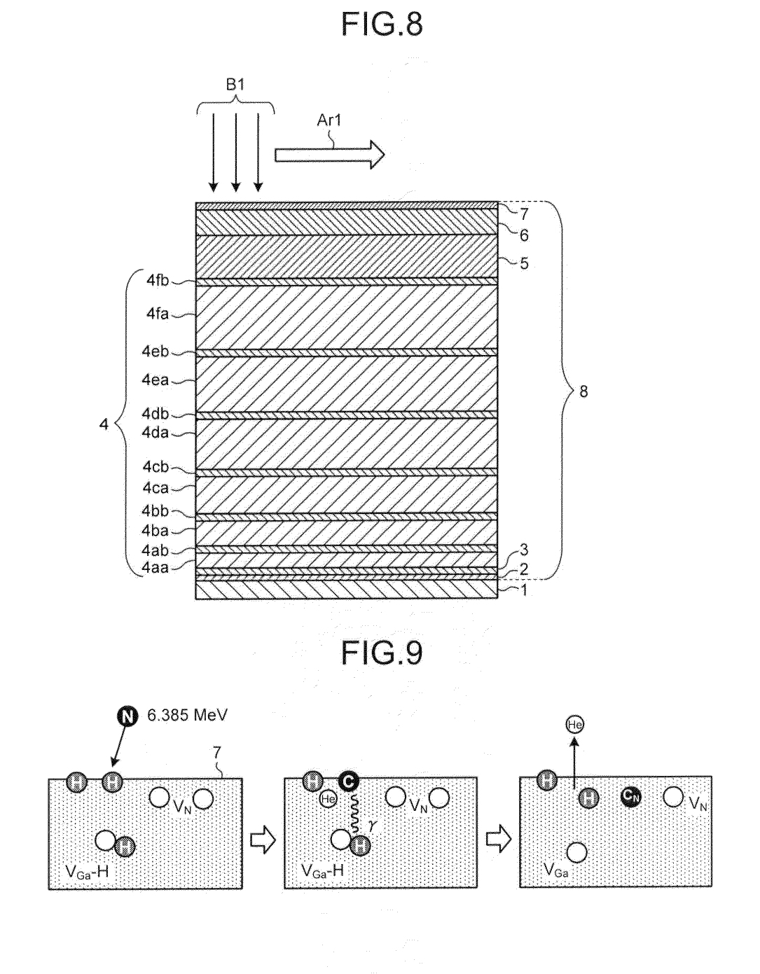

FIG. 8 is a schematic for explaining a carbon doping process in the process of fabricating the HFET illustrated in FIG. 6. As illustrated in FIG. 8, the epitaxial substrate is irradiated with an N ion beam B1 accelerated to 6.385 mega electron volts at a beam current of 50 nanoamperes. The beam diameter of the beam B1 is approximately 5 millimeters.

By irradiating the epitaxial substrate with the N ion beam B1, hydrogen near the surface of the nitride-based compound semiconductor (near the surface of the AlGaN layer 7) is nuclear-transformed into carbon, through a resonant nuclear reaction of the hydrogen.

The resonant nuclear reaction will now be explained. A resonant nuclear reaction is a phenomenon in which only particles having a predetermined energy go through a nuclear reaction resonantly. In a nitrogen atom and a hydrogen atom, the following reaction occurs only when the acceleration energy is 6.385 mega electron volts:

¹⁵N+¹H→¹²C+α+γ (1)

where α represents an alpha particle (helium nucleus), and γ represents gamma rays.

A resonant nuclear reaction of hydrogen can be achieved by using a tandem accelerator (improved version of a Van de Graaff accelerator), for example. For a tandem accelerator, the facility in the Japan Atomic Energy Agency (JAEA) can be used, for example.

FIG. 9 is a schematic for explaining a reaction on the surface of the epitaxial layer 8. When the surface of the nitride-based compound semiconductor is irradiated with ¹⁵N having been accelerated by a tandem accelerator or the like to 6.385 mega electron volts, the full width at half maximum of the reaction is 1.5 kilo electron volts which is extremely narrow. Therefore, only the hydrogen atoms in a region down to a depth of approximately 10 nanometers from the surface of the epitaxial layer 8 (the surface of the AlGaN layer 7) go through a resonant nuclear reaction, whereby producing ¹²C on the surface.

The ¹²C reacts with a nitrogen vacancy V_{N} near the surface and is substituted with a nitrogen site (C_{N}). C_{N} produces shallow acceptor levels as illustrated in FIG. 4, and the residual carriers in the AlGaN layer 7 can be compensated. In addition, the donor levels on the surface can be reduced. Therefore, the Schottky leakage explained using the surface donor model can be reduced.

As indicated by Equation (1), gamma rays are emitted in the nuclear reaction. The energy of the gamma rays is 4.43 mega electron volts, and the entire nitride-based compound semiconductor layers are irradiated with the gamma rays.

The gamma rays can break the bond of V_{Ga}—H complex defect made of a gallium vacancy and hydrogen in the buffer layers 4 and 5 and the GaN layer 6. The complex defect is broken down into V_{Ga} and H. Because the residual carriers in the semiconductor are modulated by this breakdown, the intensity of a broad luminescence near 2.2 electron volts in the photoluminescence (PL) spectrum (what is called yellow luminescence) is reduced. Therefore, V_{Ga}—H breakdown can be confirmed by PL measurement. In this manner, it becomes possible to suppress characteristic changes that occur in a long-term current application, which is pointed out in T. Roy, Y. S. Puzyrev, B. R. Tuttle, D. M. Fleetwood, R. D. Schrimpf, D. F. Brown, U. K. Mishra, and S. T. Pantelides, Applied Physics Letter. 2010, vol. 96, p. 133503 and Japanese Patent Application Laid-open No. 2012-104722, which belongs to the inventors of the present invention. Because the helium atoms in the nitride-based compound semiconductors are electrically neutral, the electrical characteristics are not affected thereby at all.

On the surface of the nitride-based compound semiconductor, hydrogen atoms are present in the form of atoms or water (OH). The density is said to be between 10¹⁸ cm⁻³ and 10¹⁹ cm⁻³ in a volume density, and a sufficient amount of hydrogen atoms for supplying carbon substituting V_{N} is present.

In the manner described above, a carbon-doped region can be formed near the surface of the AlGaN layer 7. Furthermore, because the cohesive energy of the system decreases by substituting V_{N} with C_{N}, as illustrated in FIG. 5, carbon atoms produced in the resonant nuclear reaction can easily form C_{N}.

When carbon is to be doped following the method disclosed in Japanese Patent Application Laid-open No. 2007-251144 and Japanese Patent Application Laid-open No. 2010-239034, in order to dope carbon only near the surface, growing conditions need to be changed, or the growth needs to be temporarily stopped, in the middle of an epitaxial growth. Therefore, nitrogen vacancies or gallium vacancies might be formed, and the leakage current might be increased and the current collapse phenomenon might be worsened. Furthermore, because carbon atoms diffuse during the growth, the two-dimensional electron gas density in the electron transit layer might be reduced. These issues are prevented in the method using the resonant nuclear reaction of hydrogen.

Referring back to FIG. 8, under the conditions of a beam current of 50 nanoamperes and a beam diameter of 5 millimeters or so, the beam B1 would have a flux of 1×10¹² cm⁻²s⁻¹, and carbon equal to or larger than 5×10¹⁸ cm⁻³ can be doped in a region within a depth of 10 nanometers from the surface of the AlGaN layer 7 by irradiating the epitaxial substrate with the beam B1 for approximately 10 seconds. By monitoring the amount of gamma rays emitted in the nuclear reaction with a scintillation detector, in situ observation of the density of carbon produced in nuclear reactions can be carried out.

In FIG. 8, in order to irradiate the epitaxial substrate uniformly with N ions, the beam B1 is scanned relatively to the epitaxial substrate using an xy stage, as illustrated with an arrow Ar1.

Because most of the N ions thus irradiated go through nuclear reactions with hydrogen near the surface of the AlGaN layer 7, the structures under the AlGaN layer 7 is not affected. Furthermore, according to a Monte Carlo simulation using a transport of ions in matter (TRIM) code, the N ions having energy up to 6.385 mega electron volts having entered into the AlGaN layer 7 without going through a nuclear reaction do not lose energy in the AlGaN layer 7 and the GaN layer 6. In other words, such N ions do not form any irradiation defect in the AlGaN layer 7 and the GaN layer 6. Therefore, N ions not going through a nuclear reaction will not have any adverse effect to the electrical characteristics of the HFET 100.

When there are some N ions that do not go through nuclear reactions, e.g., when the number of N ions is larger than the amount of hydrogen, the N ions not going through a nuclear reaction and having energy up to 6.385 mega electron volts lose most of their energy and stop in a region between 3 micrometers to 4 micrometers from the surface of the epitaxial layer 8 (in the buffer layer 4 in this example). Irradiation defects remain in this region, but because the deep levels formed by the irradiation defects have an effect of compensating for the residual carriers in the buffer layer 4, such irradiation defects rather work advantageously in increasing the breakdown voltage and reducing the leakage current in the device.

By checking the presence or absence of irradiation defects such as inter-lattice atoms in the region between 3 micrometers to 4 micrometers from the surface of the epitaxial layer 8, it can be detected if the carbon doped in a region from the surface down to a depth of approximately 10 nanometers or so have resulted from the resonant nuclear reaction with hydrogen or from another doping method.

3. Fabricating Device:

A device of the HFET 100 is then fabricated. The device can be fabricated by applying patterning using a photolithography process, in a manner following a known process.

To form the electrodes, the source electrode 9S and the drain electrode 9D are formed as ohmic electrodes by depositing Ti (at a film thickness of 25 nanometers) and Al (at a film thickness of 300 nanometers) on the AlGaN layer 7 in the order described herein. The gate electrode 9G is formed as a Schottky electrode by depositing Ni (at a film thickness of 100 nanometers) and Au (at a film thickness of 200 nanometers) between these electrodes in the order described herein. Good ohmic characteristics are achieved by applying thermal processing at 700 degrees Celsius for 30 minutes after depositing the source electrode 9S and the drain electrode 9D.

As to the dimensional factors of the HFET 100, for example, the HFET 100 may be fabricated to have a gate length of 2 micrometers, a gate width of 0.2 millimeter, and a source-to-drain distance of 15 micrometers. A breakdown voltage of 1000 volts or higher can be ensured in the HFET 100 fabricated through the process described above.

Explained now are electrical characteristics of the HFET (example) manufactured in the manufacturing method described above and those of an HFET (comparative example) manufactured in the manufacturing method described above without the carbon doping through a resonant nuclear reaction.

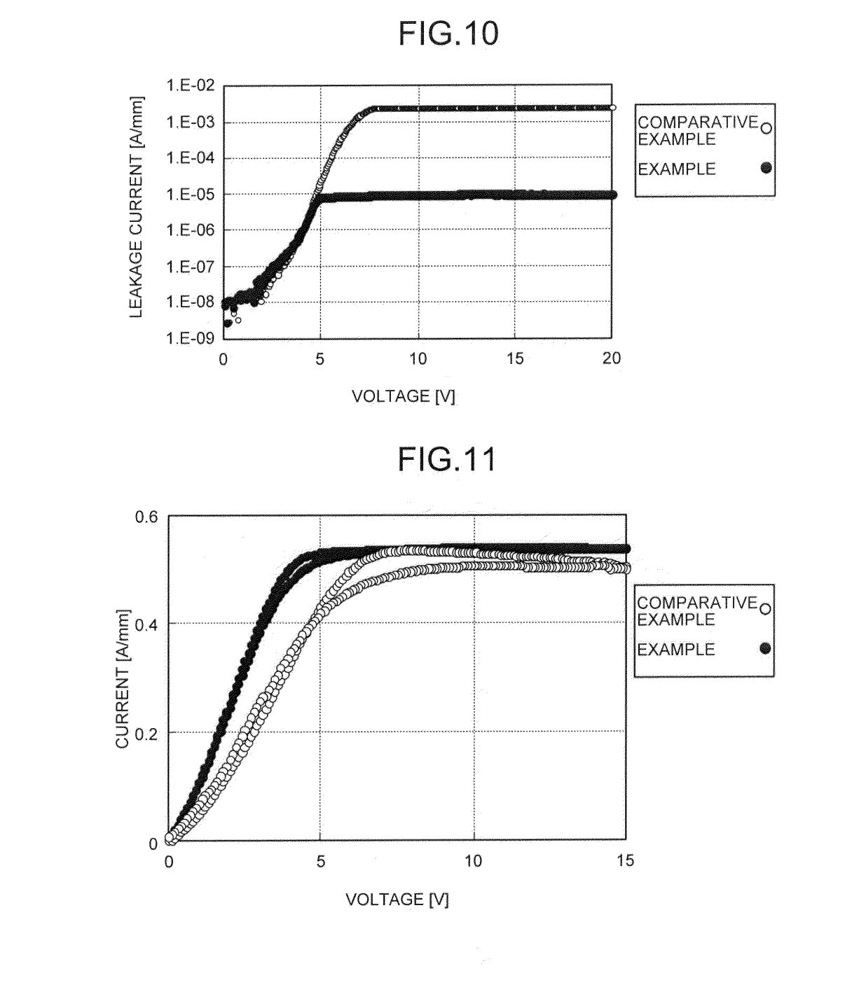

FIG. 10 is a graph of gate (Schottky) leakage characteristics of the example and the comparative example of when a gate voltage of −5 volts is applied. The horizontal axis represents the voltage between the source and the drain. The leakage current on the vertical axis is normalized to a current per gate width. As illustrated in FIG. 10, the HFET according to the example has a leakage current that is lower by two digits or larger than that of the HFET according to the comparative example.

FIG. 11 is a graph of ON characteristics of the example and the comparative example of when a voltage is applied between the source and the drain while the gate voltage is set to 0 volt. The source-to-drain voltage represented on the horizontal axis increased from 0 volt to 15 volts and then dropped from 15 volts to 0 volt.

In FIG. 11, the rise in the graph represents the ON-resistance of the device. A hysteresis occurred because of the increase and the decrease of the source-to-drain voltage. This hysteresis is attributable to a current collapse phenomenon. As it can be seen from FIG. 11, the rise in the graph is steep and the ON-resistance is low in the example. It can be also seen that the hysteresis is also small and the current collapse phenomenon is suppressed in the example.

These improvements in the characteristics are the effect of carbon doping near the surface of the AlGaN layer 7 and thereby compensating the surface donors attributable to V_{N}. Because the ON-resistance is not increased by the carbon doping, it can be considered the carbon stays only in a region down to the depth of 10 nanometers or so from the surface, without reaching the region where two-dimensional electron gas resides in the GaN layer 6.

Furthermore, because V_{Ga}—H in the GaN layer 6 and the buffer layer 4 are broken down by the gamma rays emitted in the resonant nuclear reaction, the characteristic changes caused when a current is applied for a long-term can be suppressed in the HFET 100.

### Second Embodiment

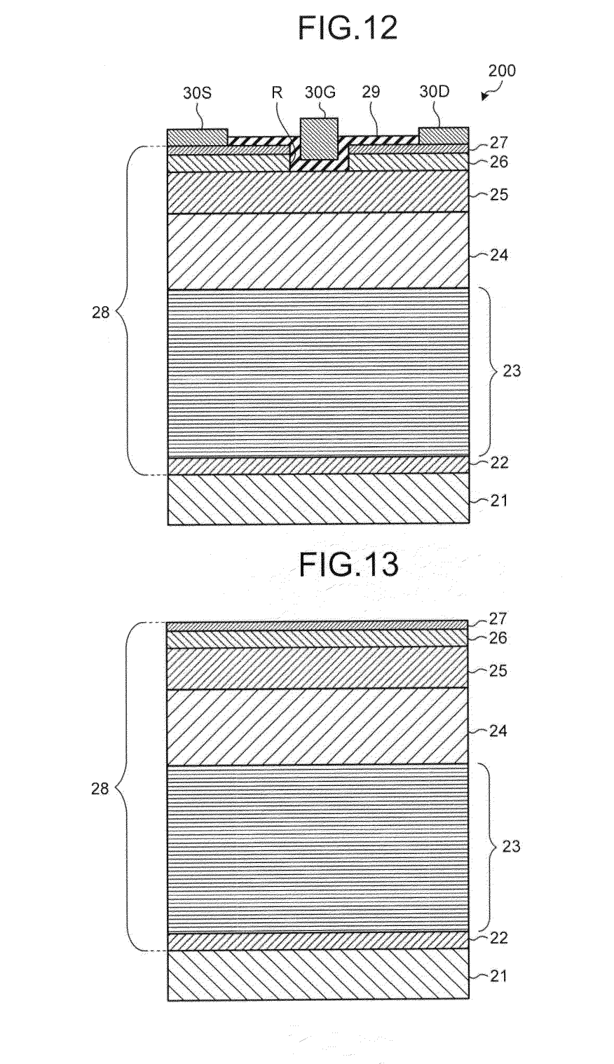

FIG. 12 is a schematic cross-sectional view of a metal-oxide-semiconductor field-effect transistor (MOSFET) that is a nitride-based compound semiconductor device according to a second embodiment of the present invention.

A MOSFET 200 includes a silicon substrate 21 whose principal plane is a (110) plane and an epitaxial layer 28. The epitaxial layer 28 includes a seed layer 22 made of AlN, a buffer layer 23 in which GaN layers and AlN layers are stacked alternately for 120 periods, a high-resistance layer 24 made of GaN, a p-GaN layer 25 in which a inversion layer (channel layer) is formed, a GaN layer 26 serving as the first nitride-based compound semiconductor layer that functions as an electron transit layer, and a AlGaN layer 27 serving as the second nitride-based compound semiconductor layer that functions as an electron-supplying layer, which are formed sequentially on the silicon substrate 21. The MOSFET 200 also includes a gate oxide film 29 covering the surface of the AlGaN layer 27 and a recess surface of a recess R formed in the GaN layer 26 and AlGaN layer 27, a source electrode 30S and a drain electrode 30D formed on the AlGaN layer 27, and a gate electrode 30G formed on the gate oxide film 29 in the recess R.

In the MOSFET 200, the inversion layer (channel layer) is formed in the p-GaN layer 25 to function as a MOSFET. The two-dimensional electron gas produced at the interface between the GaN layer 26 and the AlGaN layer 27 on the p-GaN layer 25 functions as an electrical field relaxing layer (reduced surface (RESURF) layer) and a drift layer. In this structure, because the two-dimensional electron gas layer functions as a drift layer, the ON-resistance can be reduced, advantageously.

Furthermore, the MOSFET 200 has a carbon-doped region near the surface of the AlGaN layer 27 and because nitrogen vacancies near the surface are substituted with carbon atoms, the leakage current that uses the AlGaN surface as a path is reduced, and a current collapse phenomenon is reduced as well.

An example of a method for manufacturing the MOSFET 200 will now be explained. FIG. 13 is a schematic for explaining a process of fabricating an epitaxial substrate in the process of manufacturing the MOSFET 200 illustrated in FIG. 12.

1. Method for Manufacturing Epitaxial Substrate:

To begin with, the epitaxial substrate is fabricated by forming the epitaxial layer 28 on the silicon substrate 21.

Specifically, TMAl and NH₃ are introduced at a flow rate of 175 μmol/min and a flow rate of 35 L/min, respectively, into MOCVD equipment in which the silicon substrate 21 (with a plane orientation (110)) having been grown in a CZ process and having a thickness of 1 millimeter is installed, and the seed layer 22 made of AlN having a layer thickness of 40 nanometers is epitaxially grown on the silicon substrate 21 at a growth temperature of 1000 degrees Celsius.

When the silicon substrate 21 with a plane orientation (110) is used, the dislocation density can be reduced, advantageously, compared with when a silicon substrate with a plane orientation (111) is used.

The buffer layer 23 is then formed by growing a layer made of a pair of an AlN layer having a layer thickness of 7 nanometers and a GaN layer having a layer thickness of 21 nanometers, for example, repetitively for 120 periods under a condition of a growth temperature of 1050 degrees Celsius and a growth pressure of 200 Torr. By providing the buffer layer 23, cracking of the epitaxial layer 28 is suppressed, and the amount of warpage can also be controlled.

The flow rates of TMAl, TMGa, and NH₃ of when the AlN layer and the GaN layer are grown are 195 μmol/min, 58 μmol/min, and 12 L/min, respectively.

The high-resistance layer 24 made of GaN is then stacked at a layer thickness of 100 nanometers, under conditions of a growth temperature of 1050 degrees Celsius and a growth pressure of 50 Torr. The flow rates of TMGa and NH₃ of when the high-resistance layer 24 is formed is 58 μmol/min and 12 L/min, respectively. A carbon density in the high-resistance layer 24 equal to or larger than 1×10¹⁸ cm⁻³ is preferable because such a density has an effect of reducing a buffer leakage.

TMGa and NH₃ are then introduced at a flow rate of 19 μmol/min and a flow rate of 12 L/min, respectively, and the p-GaN layer 25 is grown to a layer thickness of 450 nanometers. The growth temperature is 1050 degrees Celsius, and the growth pressure is 200 Torr. Mg is doped in the p-GaN layer 25 as a p-type dopant so as to acquire an acceptor density of 1×10¹⁷ cm⁻³. Mg may be doped by using bis(cyclopentadienyl)magnesium (Cp₂Mg) as a source gas. The p-type dopant may also be Zn or Be.

By doping a transition metal in the p-GaN layer 25 simultaneously with Mg that is a p-type dopant, n-type residual carriers can be compensated, and the device breakdown voltage can be improved. At this time, the density of the transition metal is preferably nearly equal to or lower than the acceptor density in the p-GaN layer 25. When the density of the transition metal is high, the ON-resistance of the device could be increased, disadvantageously.

When Fe is doped as an example of a transition metal, bis(cyclopentadienyl)iron (Cp₂Fe) as an organic material of Fe is introduced at a flow rate of 5 standard cc/min when the p-GaN layer 25 is grown. In this manner, Fe is doped in the p-GaN layer 25 at 5×10¹⁶ cm⁻³.

As an organic material for Fe, bis(ethylcyclopentadienyl)iron (EtCp₂Fe) may also be used.

When Ni is doped as a transition metal, allyl(cyclopentadienyl)nickel (AllylCpNi), bis(cyclopentadienyl)nickel (Cp₂Ni), tetrakis(phosphorus trifluoride)nickel (Ni(PF₃)₄), or the like may be used as an organic raw material.

TMGa and NH₃ are then introduced at a flow rate of 19 μmol/min and a flow rate of 12 L/min, respectively, and the GaN layer 26 functioning as an electron transit layer is stacked at a layer thickness of 50 nanometers under conditions of a growth temperature of 1050 degrees Celsius and a growth pressure of 200 Torr.

TMAl, TMGa, and NH₃ are further introduced at a flow rate of 100 μmol/min, a flow rate of 19 μmol/min, and a flow rate of 12 L/min, respectively, and the AlGaN layer 27 functioning as an electron transit layer is stacked at a layer thickness of 20 nanometers at a growth temperature of 1050 degrees Celsius. The aluminum composition of the AlGaN layer 27 is 0.22. The aluminum composition can be evaluated from X-ray diffraction, for example.

Through the manufacturing process described above, the epitaxial substrate is fabricated.

2. Doping Carbon Using Tandem Accelerator:

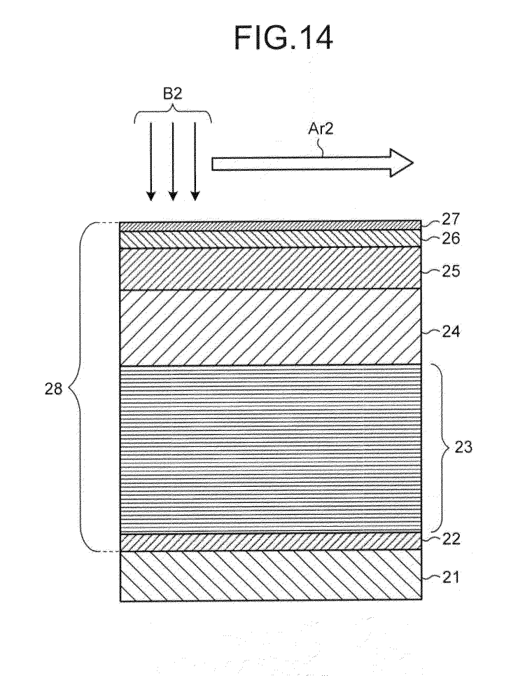

Carbon is then doped through a resonant nuclear reaction of hydrogen by irradiating the epitaxial substrate fabricated at the above-described process 1 with nitrogen ions. FIG. 14 is a schematic for explaining a process of carbon doping in the process of manufacturing the MOSFET illustrated in FIG. 12. As illustrated in FIG. 14, the epitaxial substrate is irradiated with an N ion beam B2 accelerated to 6.385 mega electron volts at a beam current 50 nanoamperes, and the beam B2 is scanned relatively to the epitaxial substrate, as illustrated with an arrow Ar2. The irradiation conditions and the like are the same as those according to the first embodiment. Through this process, carbon is doped in a region down to a depth of 10 nanometers or so from the surface of the AlGaN layer 27.

3. Fabricating Device:

A device of the MOSFET 200 is then fabricated. To begin with, a SiO₂ film is formed on the AlGaN layer 27 through plasma-enhanced chemical vapor deposition (CVD). Photoresist is then applied onto the SiO₂ film, and patterning is applied using a photolithography process. Etching is then performed using a hydrofluoric acid-based solution, and an opening is formed in the SiO₂ film at a position where the gate electrode 30G is to be formed.

Dry etching equipment is then used to form the recess R by etching the AlGaN layer 27, the GaN layer 26, and the p-GaN layer 25. The depth to which the recess R is etched is 20 nanometers from the interface between the GaN layer and the p-GaN layer. After applying dry etching, the SiO₂ film is removed using a hydrofluoric acid-based solution.

The SiO₂ film functioning as the gate oxide film 29 is then stacked through plasma-enhanced CVD at a thickness of 60 nanometers in a manner covering the recess surface of the recess R and the surface of the AlGaN layer 27.

A part of the gate oxide film 29 is then removed by etching using a hydrofluoric acid-based solution, and the source electrode 30S and the drain electrode 30D are formed in the region thus removed on the surface of the AlGaN layer 27. The source electrode 30S and the drain electrode 30D are brought into ohmic contact with the two-dimensional electron gas layer at the interface between the AlGaN layer 27 and the GaN layer 26 and is structured with Ti (with a film thickness of 25 nanometers)/Al (a film thickness of 300 nanometers), for example. Each of the metallic films making up the electrodes can be formed through spattering or vacuum deposition. Good ohmic characteristics are achieved by applying thermal processing at 700 degrees Celsius for 30 minutes after fabricating the source electrode 30S and the drain electrode 30D.

Finally, the gate electrode 30G is formed through low-pressure CVD on the gate oxide film 29 in the recess R using polysilicon that is doped to a p-type with phosphorus (P).

Dimensional factors of the MOSFET 200 include, for example, a gate-to-source inter-electrode distance of 5 micrometers, a gate-to-drain distance of 20 micrometers, a gate length of 2 micrometers, and a gate width of 0.2 millimeter.

The MOSFET 200 manufactured through the process described above can have a breakdown voltage equal to or larger than 600 volts. Furthermore, because V_{N} near the surface of the AlGaN layer 27 is substituted with C_{N}, the leakage current using the AlGaN surface between the gate electrode and the drain electrode as a path is reduced, and the current collapse phenomenon can be suppressed.

Furthermore, because V_{Ga}—H in the buffer layer 23 is broken down by the gamma rays emitted in the resonant nuclear reaction, the characteristic changes caused by a long-term current application cannot be observed. Furthermore, in addition to these advantageous effects, because the gamma rays are capable of breaking the bond of a complex defect (Mg—H) made of Mg and hydrogen in the p-GaN layer 24, the activation rate of the doped acceptors is enhanced. In this manner, variations in the threshold among different devices of the MOSFET 200 can be suppressed, advantageously.

### Third Embodiment

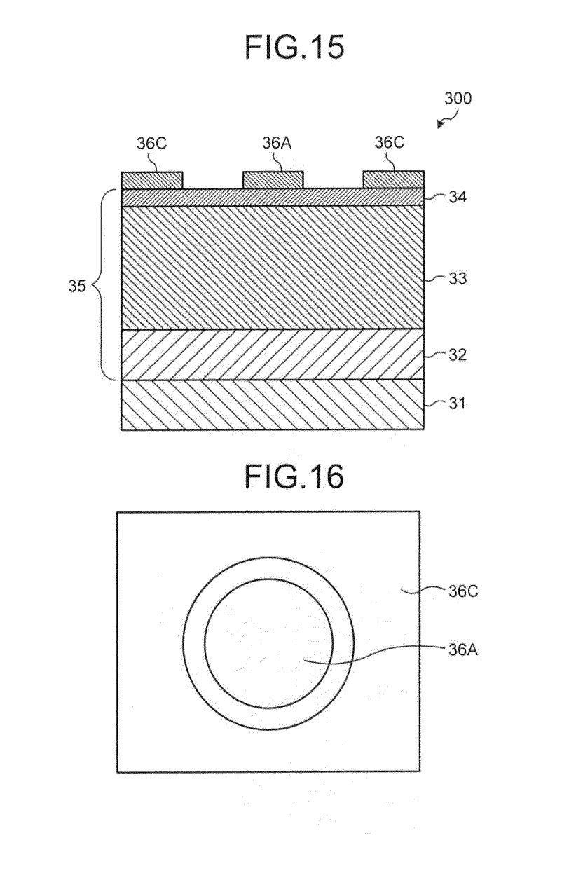

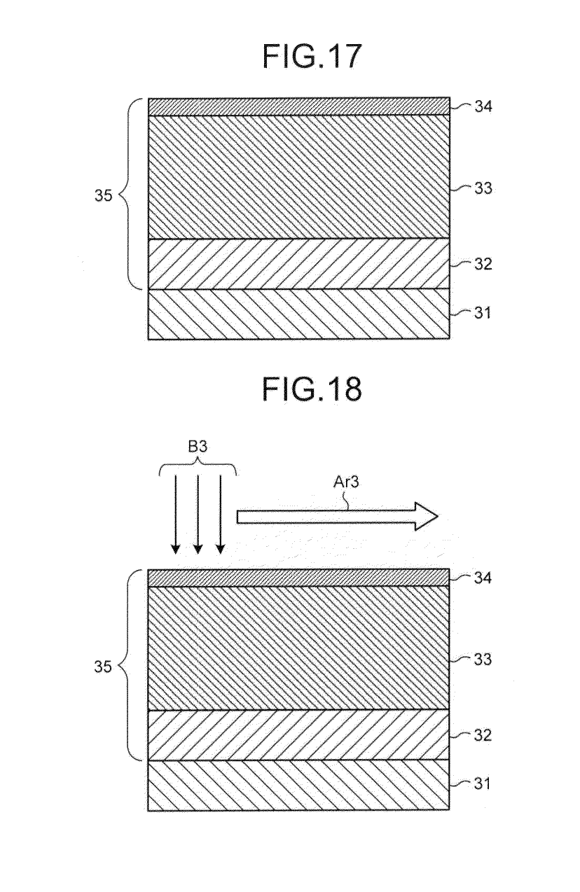

FIG. 15 is a schematic cross-sectional view of a Schottky barrier diode (SBD) that is a nitride-based compound semiconductor device according to a third embodiment of the present invention. FIG. 16 is a top view of the SBD illustrated in FIG. 15.

An SBD 300 includes a sapphire substrate 31 and an epitaxial layer 35. The epitaxial layer 35 includes a buffer layer 32 made of GaN, a GaN layer 33 serving as a first nitride-based compound semiconductor layer that functions as an electron transit layer, and an AlGaN layer 34 serving as a second nitride-based compound semiconductor layer that functions as an electron-supplying layer, which are formed sequentially on the sapphire substrate 31. The SBD 300 also includes an anode electrode 36A and a cathode electrode 36C that are formed on the AlGaN layer 34. The anode electrode 36A is a circular electrode, and the cathode electrode 36C is formed in a manner surrounding the anode electrode 36A.

In the SBD 300, because the AlGaN layer 34 has a carbon-doped region near the surface thereof, and because nitrogen vacancies near the surface are substituted with carbon atoms, the Schottky leakage current is low, and a current collapse phenomenon is reduced.

An example of a method for manufacturing the SBD 300 will now be explained. FIG. 17 is a schematic for explaining a process of fabricating an epitaxial substrate in the process of manufacturing the SBD 300 illustrated in FIG. 15.

1. Fabricating Epitaxial Substrate:

To begin with, the epitaxial substrate is fabricated by forming the epitaxial layer 35 on the sapphire substrate 31.

Specifically, TMGa and NH₃ are introduced at a flow rate of 14 μmol/min and a flow rate of 12 L/min, respectively, into MOCVD equipment in which the sapphire substrate 31 having a thickness of 500 micrometers and a diameter of 2 inches (approximately 50 millimeters) is installed, and the buffer layer 32 made of GaN and having a layer thickness of 30 nanometers is epitaxially grown at a growth temperature of 550 degrees Celsius.

TMGa and NH₃ are then introduced at a flow rate of 19 μmol/min and a flow rate of 12 L/min, respectively, and the GaN layer 33 functioning as an electron transit layer is grown to a layer thickness of 3 micrometers.

The growth temperature is 1050 degrees Celsius, and the growth pressure is 100 Torr.

TMAl, TMGa, and NH₃ are then introduced at a flow rate of 100 μmol/min, a flow rate of 19 μmol/min, and a flow rate of 12 L/min, respectively, and the AlGaN layer 34 functioning as an electron-supplying layer and having a layer thickness of 30 nanometers is epitaxially grown on the GaN layer 33 at a growth temperature of 1050 degrees Celsius. The aluminum composition of the AlGaN layer 34 is 0.24. The epitaxial substrate is fabricated through the manufacturing process explained above.

Alternatively, the epitaxial substrate may also be fabricated by forming the nitride-based compound semiconductor layers on the substrate through hydride vapor phase epitaxy (HVPE), molecular beam epitaxy (MBE), laser ablation, or the like.

2. Doping Carbon through Ion Implantation:

Carbon is then doped in the epitaxial substrate fabricated at the above-described process 1 through ion implantation following the process described below. In this manner, carbon is doped in a region near the surface of the AlGaN layer 34.

To begin with, a SiO₂ film serving as a surface protection film is stacked on the AlGaN layer 34 at a film thickness of 10 nanometers through plasma CVD.

Carbon ions are then implanted. FIG. 18 is a schematic for explaining the process of carbon doping in the process of manufacturing the SBD 300 illustrated in FIG. 15. As illustrated in FIG. 18, carbon ions are implanted into the surface of the epitaxial layer 35 with a low accelerating voltage that is lower than 5 kilovolts, and a carbon ion beam B3 is scanned relatively to the surface as illustrated with an arrow Ar3. The irradiation time or the beam current (flux) is adjusted so that the peak of the carbon density is at 1×10¹⁹ cm⁻³. After implanting ions, the SiO₂ film serving as a surface protection film is removed using a hydrofluoric acid-based solution.

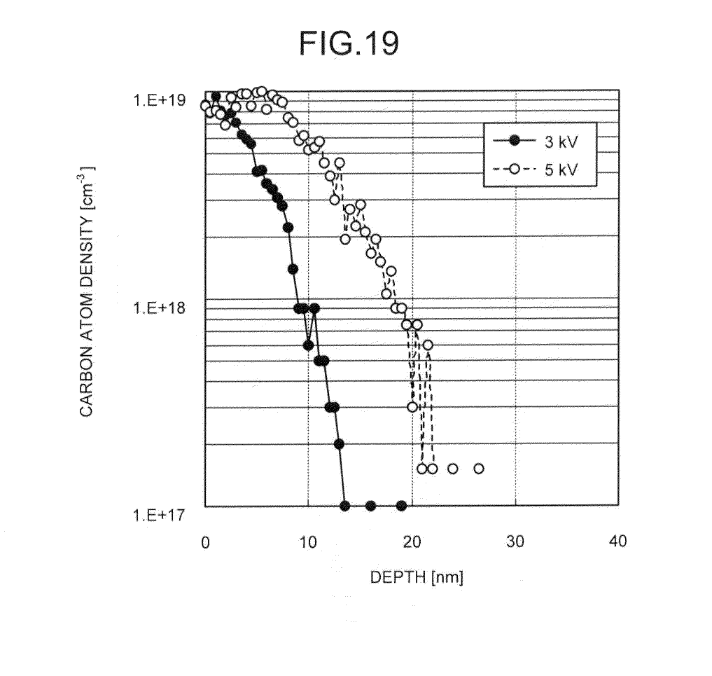

FIG. 19 is a graph of a profile of implanted carbon atoms calculated using TRIM code. In FIG. 18, the surface of the AlGaN layer 34 is positioned at a depth of 0 nanometer. As illustrated in FIG. 19, because, with the 5 kilovolt accelerating voltage, the carbon atoms penetrate into a depth of 20 nanometers or so from the surface, the carbon atoms might adversely affect the two-dimensional electron gas at the interface between the AlGaN layer 34 and the GaN layer 33. Therefore, the accelerating voltage is preferably lower than 5 kilovolts, and more preferably equal to or lower than 3 kilovolts. The accelerating voltage may be adjusted as appropriate to a level not adversely affecting the two-dimensional electron gas, depending on the layer thickness of the AlGaN layer 34.

3. Fabricating Device:

A device of the SBD 300 is then fabricated. The device can be fabricated by performing patterning using a photolithography process, in a manner following a known process.

As to the formation of the electrodes, the cathode electrode 36C is formed as an ohmic electrode by depositing Ti (at a film thickness of 25 nanometers) and Al (at a film thickness of 300 nanometers) on the AlGaN layer 34 in the order described herein. The anode electrode 36A is formed as a Schottky electrode by depositing Ni (at a film thickness of 100 nanometers) and Au (at a film thickness of 200 nanometers) in the area surrounded by the electrode in the order described herein. The anode electrode 36A is a circular electrode having a diameter of 160 micrometers, and the pitch between the anode electrode 36A and the cathode electrode 36C is 10 micrometers. Good ohmic characteristics are achieved by applying thermal processing at 700 degrees Celsius for 30 minutes after depositing the cathode electrode 36C.

Because, in the SBD 300 manufactured through the process described above, V_{N} near the surface of the AlGaN layer 27 is substituted with C_{N}, the Schottky leakage current is reduced and the current collapse phenomenon is suppressed, compared with an SBD without being applied with carbon doping.

Furthermore, the epitaxial layer 35 may be irradiated with synchrotron radiation or thermal neutrons in the hard X-ray range after the epitaxial substrate is fabricated so that V_{Ga}—H in the buffer layer 32 of the SBD 300 are broken down and characteristic changes caused by a long-term current application are suppressed.

In the embodiments, as a material for the anode electrode or the gate electrode that is a Schottky electrode, Pt or Pd which has a high work function may be used.

Furthermore, in the embodiments, a substrate such as a silicon substrate, a GaN substrate, a SiC substrate, a sapphire substrate, a ZnO substrate, or a β-Ga₂O₃ substrate may be used as the substrate as appropriate.

Furthermore, in the embodiments, the compositions of the AlGaN layers serving as the second nitride-based compound semiconductor layer may be AlₓGa₁₋ₓN (0<x≦1). The aluminum composition x is preferably equal to or lower than 0.5, and within a range between 0.20 and 0.25, for example. Furthermore, the layer thickness of the AlGaN layers may be between 20 nanometers and 30 nanometers.

Furthermore, the first nitride-based compound semiconductor layer and the second nitride-based compound semiconductor layer are not limited to a GaN layer and an AlGaN layer, respectively. The first nitride-based compound semiconductor layer may be any nitride-based compound semiconductor having any composition such as AlₓGa₁₋ₓN (0≦x≦1). The second nitride-based compound semiconductor layer may be any nitride-based compound semiconductor having a composition with a band gap larger than that of the first nitride-based compound semiconductor layer.

Furthermore, the nitride-based compound semiconductor device according to the present invention includes a field-effect transistor, a Schottky barrier diode, and various types of semiconductor devices, for example, and the type of the device is not particularly limited.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A nitride-based compound semiconductor device comprising:
a substrate;
a first nitride-based compound semiconductor layer that is formed above the substrate with a buffer layer interposed therebetween;
a second nitride-based compound semiconductor layer that is formed on the first nitride-based compound semiconductor layer and that has a larger band gap than a band gap of the first nitride-based compound semiconductor layer; and
an electrode that is formed on the second nitride-based compound semiconductor layer, wherein
the second nitride-based compound semiconductor layer has a region in which carbon is doped near a surface of the second nitride-based compound semiconductor layer.

2. The nitride-based compound semiconductor device according to claim 1, wherein the region in which the carbon is doped has a depth of equal to or smaller than 10 nanometers from the surface of the second nitride-based compound semiconductor layer.

3. The nitride-based compound semiconductor device according to claim 1, wherein the carbon is doped using a resonant nuclear reaction with hydrogen.

4. The nitride-based compound semiconductor device according to claim 2, wherein the carbon is doped through ion implantation.

5. The nitride-based compound semiconductor device according to claim 1, wherein an irradiation defect is formed in a region at 3 micrometers to 4 micrometers from the surface of the second nitride-based compound semiconductor layer.

6. The nitride-based compound semiconductor device according to claim 1, wherein the buffer layer or the second nitride-based compound semiconductor layer has a gallium vacancy formed by breakdown of a complex defect consisting of the gallium vacancy and hydrogen.

7. The nitride-based compound semiconductor device according to claim 1, wherein the first nitride-based compound semiconductor layer is made of GaN and the second nitride-based compound semiconductor layer is made of AlₓGa₁₋ₓN (0<x≦1).

8. The nitride-based compound semiconductor device according to claim 1, wherein the nitride-based compound semiconductor device is a field-effect transistor or a Schottky barrier diode.

9. The nitride-based compound semiconductor device according to claim 1, wherein the nitride-based compound semiconductor device is a Schottky barrier diode.
